(19) United States
(12) Patent Application Publication
(10) Pub. No.: US 2021/0343989 A1
(43) Pub. Date: Nov. 4, 2021

(54) DISPLAY DEVICE

(71) Applicant: SHARP KABUSHIKI KAISHA, Sakai City, Osaka (JP)

(72) Inventors: HIROKI IMABAYASHI, Sakai City, Osaka (JP); SHOTA OKAMOTO, Sakai City, Osaka (JP); YOUHEI NAKANISHI, Sakai City, Osaka (JP); MASAYUKI KANEHIRO, Sakai City, Osaka (JP); HISAYUKI UTSUMI, Sakai City, Osaka (JP)

(21) Appl. No.: 17/280,155

(22) PCT Filed: Sep. 28, 2018
(86) PCT No.: PCT/JP2018/036357

§ 371 Date: Mar. 25, 2021

(51) Int. Cl. H01L 51/52

(52) U.S. Cl. CPC H01L 51/5268; H01L 51/5012

(57) ABSTRACT

A display device (500) includes a sub-pixel (100) including a light-emitting element layer (10). The sub-pixel (100) includes: a first electrode (12); an edge cover (11); a projection (15) projecting from the front face of the first electrode (12); and a functional layer (13). With respect to the front face of the first electrode (12) where a first height (h1) is a height up to a front face of a protrusion of the functional layer (13) provided along an edge of the projection (15), a second height (h2) is a height up to a tip of the projection (15), and a third height (h3) is a height up to a front face of the edge cover (11), the second height (h2) is greater than the first height (h1) and smaller than the third height (h3).

### TECHNICAL FIELD

The present invention relates to a display device.

### BACKGROUND ART

Techniques to manufacture a light-emitting cell to be used for an organic EL display include solution processing such as ink-jet printing. This solution processing involves, for example, delivering or applying droplets, of a material of a functional layer (a light-emitting element layer) such as a light-emitting layer, to a region surrounded by a partition wall formed in a position of a pixel, and drying the droplets. Drying the droplets, however, produces the coffee ring effect causing a component of a film to be segregated along an outer periphery of a droplet. A problem here is that, in the light-emitting layer, the effect causes an excessive variation in film thickness between an outer periphery and a center of the pixel region. In use of the solution processing, such a problem makes it difficult to control each functional layer to have an optimum film thickness, posing a challenge to optimize a characteristic of a light-emitting cell.

To overcome this problem, Patent Document 1 discloses a technique to use, as a light-emitting region, a region having a steady film thickness alone in a layer having a coffee ring.

### CITATION LIST

### Patent Literature

[Patent Document 1] Japanese Unexamined Patent Application Publication No. 2010-177154 published on Aug. 12, 2010

### SUMMARY OF INVENTION

### Technical Problem

The above technique, however, merely allows only a small portion of the cell to emit light; that is, the light-emitting area is smaller than, or equal to, one fourteenth of an area surrounded by the partition wall. In view of the above problem, the present invention is intended to provide a display device having a wide light-emitting area.

### Solution to Problem

In order to solve the above problem, a display device according to this embodiment includes a sub-pixel including a light-emitting element layer. The sub-pixel includes: a first electrode; an edge cover overlapping an end of a front face of the first electrode; a projection projecting from the front face of the first electrode; and a functional layer shaped into an island for each of sub-pixels including the sub-pixel, and formed on the front face of the first electrode. With respect to the front face of the first electrode where a first height is a height up to a front face of a protrusion of the functional layer provided along an edge of the projection, a second height is a height up to a tip of the projection, and a third height is a height up to a front face of the edge cover, the second height is greater than the first height and smaller than the third height.

### Advantageous Effects of Invention

An aspect of the present invention can provide a display device having a wide light-emitting area.

### BRIEF DESCRIPTION OF DRAWINGS

FIG. 1 is a top view of a display device according to the embodiments.

FIG. 2 is a cross-sectional view taken along arrows B-B of FIG. 1.

FIG. 3 is a flowchart illustrating a method for manufacturing the display device according to the embodiments.

FIG. 4 is a cross-sectional view schematically illustrating a sub-pixel of the display device according to a first embodiment of the present invention.

FIG. 5 is a top view schematically illustrating a disposition of a projection inside the sub-pixel according to the first embodiment of the present invention.

FIG. 6 (a) to FIG. 6 (c) are top views each schematically illustrating a projection according to first to third modifications of the present invention.

FIG. 7 is a cross-sectional view schematically illustrating the sub-pixel of the display device according to a second embodiment of the present invention.

FIG. 8 is a cross-sectional view schematically illustrating the sub-pixel of the display device according to a third embodiment of the present invention.

FIG. 9 is a cross-sectional view schematically illustrating a film formed on a sub-pixel of a display device according to a comparative example.

### DESCRIPTION OF EMBODIMENTS

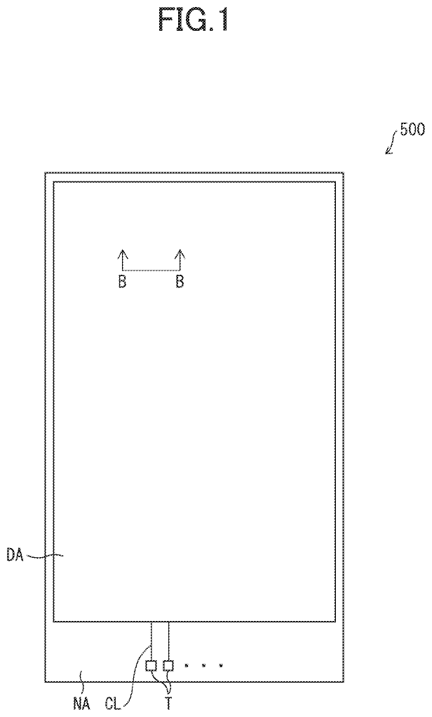

Given below with FIGS. 1 to 3 is a common description of a structure of a display device 500, citing an organic light-emitting diode (OLED) display as an example.

In the description below, the term “same layer” means that constituent features are formed in the same process. The term “lower layer (or layer below)” means that a constituent feature is formed in a previous process before a comparative layer is formed. The term “upper layer (or layer above)” means that a constituent feature is formed in a successive process after a comparative layer is formed.

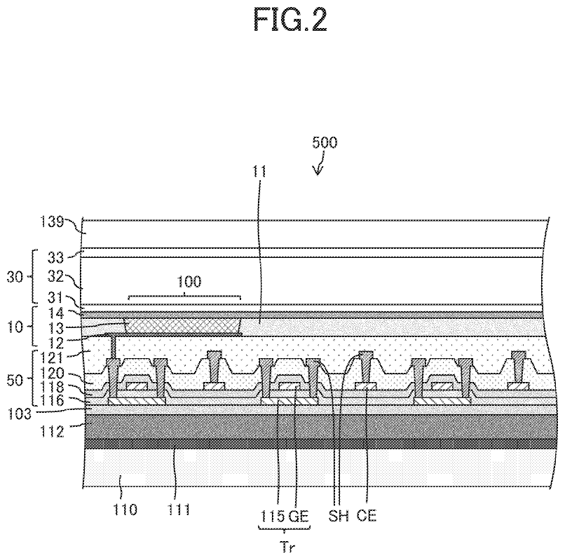

FIG. 1 is a top view of the display device 500 according to the embodiments. FIG. 2 is a cross-sectional view taken along arrows B-B of FIG. 1. As illustrated in FIG. 1, the display device 500 according to the embodiments includes: a display region DA; and a frame region NA around, and adjacent to, the display region DA. The frame region NA in FIG. 1 has an end provided with a terminal T. Mounted on the terminal T is a not-shown driver to supply, through a connection wire CL from the display region DA, a signal for driving light-emitting elements in the display region DA.

With reference to FIG. 2, described below in detail is a configuration of each of the layers in the display region DA of the display device 500 according to the embodiments.

As illustrated in FIG. 2, the display device 500 according to the embodiments includes: a lower-face film 110; a bonding layer 111; a resin layer 112; a barrier layer 103; a thin-film transistor (TFT) layer 50; a light-emitting element layer 10; and a scaling layer 30 in the stated order from below. The display device 500 may further include a functional film 139 provided above the sealing layer 30, and having such functions as optical compensation, touch sensing, and protection.

The lower-face film 110, serving as a base-material film of the display device 500, may contain, for example, an organic resin material. The bonding layer 111, bonding the lower-face film 110 and the resin layer 112 together, may be formed of a conventionally known adhesive. The resin layer 12 contains polyimide as a material.

When the display device 500 is in use, the barrier layer 103 keeps such an impurity as water or oxygen from reaching the TFT layer 50 or the light-emitting element layer 10. An example of the barrier layer 103 includes a silicon oxide film, a silicon nitride film, or a silicon oxide nitride film formed by chemical vapor deposition (CVD), or a multilayer film including these films.

The TFT layer 50 includes: a semiconductor film 115; a first inorganic insulating film 116 (a gate insulating film); a gate electrode GE; a second inorganic insulating film 118: a capacitance electrode CE; a third inorganic insulating film 120; a source wire SH (a metal wire layer); and a planarization film 121 (an interlayer insulating film) in the stated order from below. A TFT Tr is formed to include the semiconductor film 115, the first inorganic insulating film 116 and the gate electrode GE.

The semiconductor film 115 is formed of, for example, low-temperature polysilicon (LTPS) or an oxide semiconductor. Note that, in FIG. 1, the TFT including the semiconductor film 115 as a channel is of a top gate structure. Alternatively, the TFT may be of a bottom gate structure (when the channel of the TFT is, for example, an oxide semiconductor).

The gate electrode GE, the capacitance electrode CE, or the source wire SH may contain at least one of such metals selected from a group of aluminum (Al), tungsten (W), molybdenum (Mo), tantalum (Ta), chromium (Cr), titanium (Ti), and copper (Cu). That is, the gate electrode GE, the capacitance electrode CE, or the source wire SH is a monolayer film or a multilayer film made of these metals.

The first inorganic insulating film 116, the second inorganic insulating film 118, and the third inorganic insulating film 120 can be, for example, a silicon oxide (SiOx) film or a silicon nitride (SiNx) film formed by the CVD, or a multilayer film including these films.

The planarization film 121 may be made of an applicable photosensitive organic material such as polyimide and acrylic.

The light-emitting element layer 10 (e.g. an organic light-emitting diode layer) includes: a pixel electrode 12 (a first electrode, for example, an anode); a cover film (an edge cover) 11 covering an edge of the pixel electrode 12; a functional layer 13; and an upper electrode (a second electrode, for example, a cathode) 14 in the stated order from below. For each of the sub-pixels 100, the light-emitting element layer 10 includes: a light-emitting element (e.g. an organic light-emitting diode or OLED) including the pixel electrode 12 shaped into an island, the functional layer 13 shaped into an island, and the upper electrode 14; and a sub-pixel circuit driving the light-emitting element. Moreover, in the TFT layer 50, the TFT Tr is formed for each sub-pixel circuit, and the sub-pixel circuit is controlled through the control of the TFT Tr.

In plan view, the pixel electrode 12 is positioned to overlap the planarization film 121 and a contact hole that is an opening in the planarization film 121. The pixel electrode 12 is electrically connected through the contact hole to the source wire SH. Hence, the pixel electrode 12 is supplied with a signal of the TFT layer 50 through the source wire SH. Note that the pixel electrode 12 may have a film thickness of, for example, 2 nm.

The pixel electrode 12 is shaped into an island for each of the sub-pixels 100. The pixel electrode 12 includes, for example, indium tin oxide (ITO) and an alloy containing Ag stacked on top of an other, and reflects light.

The upper electrode 14 is shaped into a monolithic form as a common layer for the sub-pixels 100. The upper electrode 14 can be formed of a light-transparent conductive material such as indium tin oxide (ITO) and indium zinc oxide (IZO).

The cover film 11, an organic insulating film, is formed in a position for covering the edge of the pixel electrode 12. The cover film 11 includes an opening for each of the sub-pixels 100 to partially expose the pixel electrode 12. The cover film 11 can be made of an applicable material such as polyimide.

The functional layer 13 is, for example, patterned for each sub-pixel 100, and includes, for example, a hole-transport layer and a light-emitting layer stacked on top of an other in the stated order from below (not shown).

In the embodiments, the functional layer 13 may include a common layer (not shown). The common layer is shaped into a monolithic form in common among the sub-pixels 100, and includes, for example, an electron-transport layer above the light-emitting layer. An example of a layer formed of the functional layer 13 and the common layer includes a hole-injection layer, a hole-transport layer, a light-emitting layer, an electron-transport layer, and an electron-injection layer stacked on top of an other in the stated order from below.

In the functional layer 13, one layer may have two or more functions. For example, the hole-injection layer and the hole-transport layer may be replaced with one layer serving as both the hole-injection layer and the hole-transport layer. Moreover, the electron-injection layer and the electron-transport layer may be replaced with one layer serving as both the electron-injection layer and the electron-transport layer. Furthermore, a carrier block layer may be provided as appropriate between the layers.

The functional layer 13 may have a thickness ranging, for example, from 50 nm to 250 nm. A lower limit of the thickness of the functional layer 13 is preferably 50 nm or greater, more preferably 100 nm or greater, and still more preferably 150 nm or greater. An upper limit of the thickness of the functional layer 13 is preferably 250 nm or smaller, and more preferably 200 nm or smaller.

If the light-emitting element layer 10 is an OLED layer, holes and electrons recombine together in the functional layer 13 by a drive current between the pixel electrode 12 and the upper electrode 14, which forms an exciton. While the exciton transforms to the ground state, light is released. Since the upper electrode 14 is translucent and the pixel electrode 12 is light-reflective, the light emitted from the functional layer 13 travels upward. This is how the display device 500 is of a top emission type.

The sealing layer 30 includes: a first inorganic sealing film 31 above the upper electrode 14; an organic sealing film 32 above the first inorganic sealing film 31; and a second inorganic sealing film 33 above the organic sealing film 32. The sealing layer 30 keeps impurities such as water and oxygen from reaching the light-emitting element layer 10. An example of the first and second inorganic sealing films 31 and 33 includes a silicon oxide film, a silicon nitride film, or a silicon oxide nitride film formed by the CVD, or a multilayer film including these films. The organic sealing film 32 may be made of an applicable photosensitive organic material such as polyimide or acrylic.

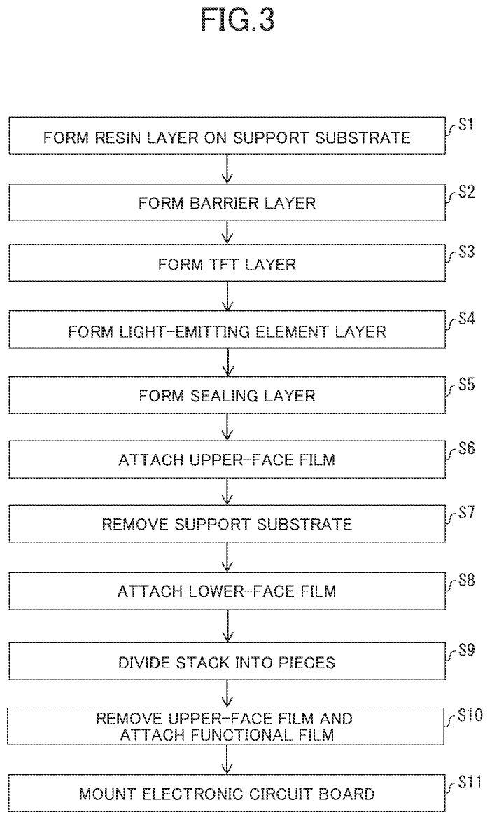

Described below is a method for manufacturing a display device according to the embodiments, with reference to a flowchart in FIG. 3. FIG. 3 is the flowchart illustrating the method for manufacturing the display device according to the embodiments.

First, at Step S1, the resin layer 112 is formed on a support substrate S that is, for example, a light-transparent mother glass substrate. At Step S2, the barrier layer 103 is formed. At Step S3, the TFT layer 50 is formed above the barrier layer 103. Simultaneously, the terminal T and the connection wire CL may also be formed together.

At Step S4, the light-emitting element layer (e.g. an OLED element layer) 5 of a top emission type is formed. At Step S4, the layers of the light-emitting element layer 10 may be formed by a conventionally known technique. In particular, the functional layer 13 may be formed by, for example, vapor deposition. At Step S5, the sealing layer 30 is formed.

At Step S6, an upper-face film is attached on the upper face of the sealing layer 30. The upper-face film, attached to the upper face of the sealing layer 30, may be formed of the same material as that of the lower-face film 110. Similar to the lower-face film 110, the upper-face film may be attached to the sealing layer 30 through the bonding layer.

Next, at Step S7, the support substrate S is removed from the resin layer 112. An example technique for removing the support substrate S may involve emitting a laser beam to a lower face of the resin layer 112 through the support substrate S to reduce bonding strength between the support substrate S and the resin layer 112, and removing the support substrate S from the resin layer 112.

At Step S8, the lower-face film 110 is attached to a lower face of the structures through the bonding layer 111. At Step S9, the stack from the lower-face film 110 to the upper-face film is separated into a plurality of pieces. At Step S10, the upper-face film is removed from the sealing layer 30, and the functional film 139 is attached to an upper face of each of the pieces. At Step S11, an electronic circuit board (e.g. an IC chip) is mounted on the terminal T, and, at Step S11, the display device 500 is finalized.

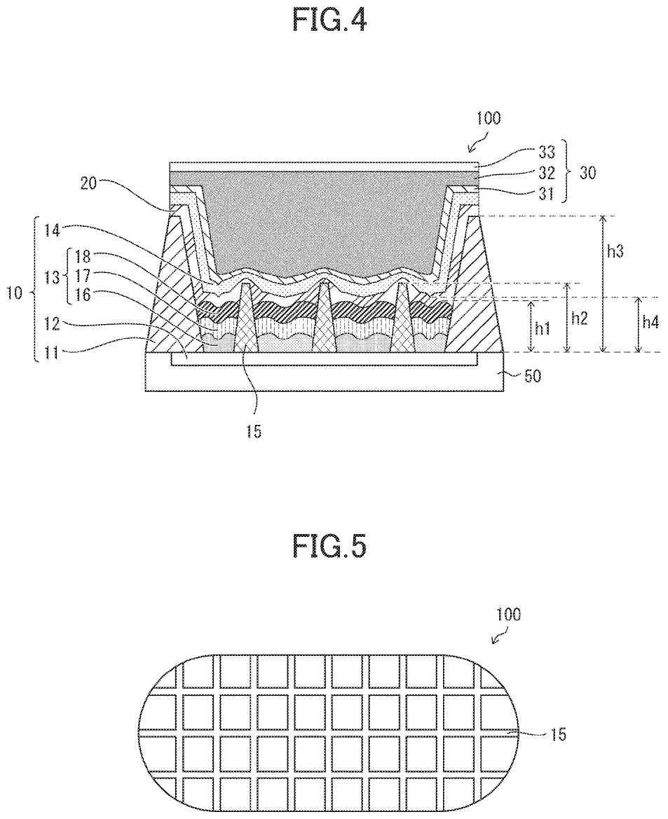

Described below are details of the embodiments, with reference to, for example, FIG. 4.

### First Embodiment

A typical display device has a plurality of pixels arranged therein. One pixel includes a set of sub-pixels in red (R), green (G), and blue (B). The display device 500 according to this embodiment also includes a plurality of pixels including the one pixel and arranged therein.

Described below is the display device 500 according to this embodiment, with reference to FIG. 4. FIG. 4 is a cross-sectional view schematically illustrating a sub-pixel of the display device according to a first embodiment of the present invention. The display device 500 according to this embodiment includes a sub-pixel 100 including the light-emitting element layer 10.

1. Outline of Sub-Pixel

[Light-Emitting Element Layer]

As illustrated in FIG. 4, the sub-pixel 100 including the light-emitting element layer 10 includes: the pixel electrode 12; the cover film 11 overlapping an end of a front face of the pixel electrode 12; a projection 15 projecting from the front face of the pixel electrode 12; and the functional layer 13 shaped into an island for each sub-pixel 100, and formed on the front face of the pixel electrode 12. Moreover, the sub-pixel 100 according to this embodiment may further include the upper electrode 14 above the functional layer 13.

Note that, in this DESCRIPTION, the pixel-electrode-12 side and the functional-layer-13 side are respectively referred to as “below” and “above.” Moreover, in each of the layers, the face above and the face below are respectively referred to a “front face” and a “back face”.

The projection 15 is formed on the front face of the pixel electrode 12. That is why a material of the functional layer 13 forms a protrusion not only on an edge of the cover film 11 but also on an edge of the projection 15 because of surface tension and the coffee ring effect. Details of the protrusion will be described in “2. Projection”. Thanks to the projection, on the edge of the cover film 11 or of the projection 15, the functional layer 13 can increase an area of a region thicker than an other region formed thinly because of the coffee ring effect. Such a feature allows the sub-pixel 100 to have a wider light-emitting area, contributing to high brightness of the light.

Here, the term “light-emitting region” of the sub-pixel 100 is a region defined by the cover film 11 and capable of emitting light. The term “light-emitting area” is a portion, of the light-emitting region, whose film thickness is suitable to emit light.

The coffee ring effect is spontaneous transportation of a substance dissolved in a liquid when the liquid dries. Specifically, in the coffee ring effect, a drying droplet produces micro convection from a center toward the outside of the liquid, and the dissolved substance moves toward outside and is deposited thick on the edge of the droplet.

(Electrode)

The pixel electrode 12 is positioned on a bottom face of the light-emitting element layer 10. On the front face of the pixel electrode 12, the projection 15 is formed to protrude upward. Details of the projection 15 will be described later in “2. Projection”. Moreover, the upper electrode 14 is stacked above, and covers an upper face of, the functional layer 13 to be described later. The upper electrode 14 is formed by, for example, vapor deposition.

(Cover Film)

The cover film 11 according to this embodiment overlaps an end of the front face of the pixel electrode 12, and covers an edge of the pixel electrode 12 in plan view. Moreover, the cover film 11 defines the functional layer 13 formed above the pixel electrode 12. Note that the cover film 11 covers neither the front face nor the back face of the light-emitting element layer 10. In plan view, the cover film 11 has an opening to expose the pixel electrode 12 and the functional layer 13. The functional layer, which is found in this exposed portion, emits light. Meanwhile, an other region; that is, a portion of the cover film 11 exposed as the upper most face, does not emit light. An example cross-section of the cover film 11 may be, but not limited to, trapezoidal.

The cover film 11 covers an edge of the pixel electrode 12, reducing the risks of electric field concentration and of a short circuit between the pixel electrode 12 and the upper electrode 14 caused when the functional layer 13 becomes thinner.

(Functional Layer)

The functional layer 13 is provided above the pixel electrode 12 and below the upper electrode 14, and emits light when energized. In the display device 500 according to this embodiment, the coffee ring effect occurs when, for example, the functional layer 13 is applied, using, for example, an ink-jet apparatus, for each of the sub-pixels 100 divided by the edge cover.

The functional layer 13 includes, for example, a hole-injection layer 16, a hole-transport layer 17, and a light-emitting layer 18 stacked on top of an other in the stated order from below.

The hole-injection layer 16 positioned below is affected relatively significantly by the coffee ring effect, and varies in film thickness; whereas, the hole-transport layer 17 and the light-emitting layer 18 formed above the hole-injection layer 16 could possibly be relieved from the variation in film thickness due to the coffee ring effect.

However, the layers included in the functional layer 13 according to this embodiment are sufficiently thin, and the coffee ring effect is expected to affect the hole-transport layer 17 and the light-emitting layer 18. The sub-pixel 100 according to this embodiment includes the projection 15, and has many thick portions caused by the coffee ring effect. That is why the inside of the sub-pixel is highly uniform in film thickness. Details of this feature will be described in “2. Projection.”

Here, in FIG. 4, the functional layer 13 is illustrated only between the cover film 11 and the projection 15, and between the projections 15. Alternatively, the functional layer 13 may be formed thinly in a position to overlap the projections 15.

The functional layer 13 according to this embodiment is applied with an ink-jet apparatus for each of the sub-pixels. Here, the functional layer 13 may include a layer formed in common among the sub-pixels.

Each of the hole-injection layer 16, the hole-transport layer 17, and the light-emitting layer 18 described above preferably contains a liquid material.

Examples of the materials of the hole-injection layer 16 and the hole-transport layer 17 include: ligroin, styrylamine, triphenylamine, porphyrin, triazole, imidazole, oxadiazole, polyallylalkane, phenylenediamine, allylamine, oxazole, anthracene, fluorenone, hydrazone, stilbene, triphenylene, and azatriphenylene; a derivative thereof; organic monomers, oligomers, or polymers of a chain conjugated system such as a polysilane-based compound, a vinylcarbazole-based compound, a thiophene-based compound, and an aniline-based compound; and an inorganic compound such as nickel oxide and tungsten oxide capable of forming a film from a solution.

Examples of the materials of the light-emitting layer 18 include: anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, and stilbene; a derivative thereof; an organic light-emitting material such as tris(8-hydroxyquinolinato)aluminium, bis(benzoquinolinato)beryllium, tri(dibenzoylmethyl)phenanthrolineeuropium, and ditluicvinylbiphenyl; and a quantum dot material containing C, Si, Ge, Sn, P, Se, Te, Cd, Zn, Mg, S, In, and O.

In each of the hole-injection layer 16, the hole-transport layer 17, and the light-emitting layer 18, the liquid material in a solution preferably has a concentration of 10 w % or lower, more preferably 6 w % or lower, and still more preferably 4 w % or lower.

Because the concentration of the liquid material is within the above range, the droplets delivered or applied by ink-jet printing or coating dry quickly, making it possible to form the layers fast.

(Common Layer)

As illustrated in FIG. 4, the sub-pixel 100 according to this embodiment may include a common layer 20 above the functional layer 13 and below the upper electrode 14. The common layer 20 may be, for example, a multilayer including an electron-transport layer and an electron-injection layer stacked on top of an other in the stated order.

A known material can be used as a material of the electron-transport layer, the electron-injection layer, or a layer serving as both the electron-injection layer and electron-transport layer; that is, a material to be used as an electron-transporting material or an electron-injecting material.

Examples of such materials include: quinolone, perylene, phenanthroline, bistyryl, pyrazine, triazole, oxazole, oxadiazole, and fluorenone; a derivative and a metal complex thereof; lithium fluoride (LiF); and inorganic nanoparticles.

More specifically, the examples include: bis[(2-diphenylphosphino)phenyl]ether (DPEPO), 4,7-diphenyl-1,10-phenanthroline (Bphen), 3,3′-bis(9H-carbazol-9-yl)biphenyl (mCBP), 2,9-dimethyl-4,7-diphenyl-1,10-phenanthroline (BCP), 1,3,5-tris(N-phenylbenzimidazol-2-yl)benzene (TPBI), 3-phenyl-4(1′-naphthyl)-5-phenyl-1,2,4-triazole (TAZ), 1,10-phenanthroline, Alq(tris(8-hydroxyquinoline)aluminum), and LiF; and nanoparticles of zinc oxide (ZnO) and magnesium-added zinc oxide (MgZnO).

[TFT Layer]

The sub-pixel 100 according to this embodiment may include, other than the light-emitting element layer 10, the TFT layer 50 including a TFT. The TFT layer 50 is a substrate to be provided below the light-emitting element layer 10.

The TFT layer 50 has an active element electrically and individually connected to the pixel electrode 12, and the active element can inject holes into the functional layer 13. Moreover, the active element is individually driven, so that the sub-pixel corresponding to the driven active element can be individually controlled.

[Sealing Layer]

The sub-pixel 100 according to this embodiment may include, other than the light-emitting element layer 10, the sealing layer 30. The sealing layer 30 is formed above the upper electrode 14 to cover the light-emitting element layer 10. The sealing layer 30 includes, for example, a first inorganic sealing film, an organic sealing film, and a second sealing film stacked on top of an other in the stated order from below.

The sub-pixel 100 of this embodiment including the light-emitting element layer 30 can keep such an impurity as water or oxygen outside from reaching inside the light-emitting element layer 10.

2. Projection

The pixel electrode 12 according to this embodiment has the front face provided with the projection 15.

(Height)

Described first is a height of the projection 15, with reference to FIG. 4.

With respect to the front face of the pixel electrode 12, h1 is a height up to a front face of a protrusion of the functional layer 13 provided along an edge of the projection 15, h2 is a height up to a tip of the projection 15, and h3 is a height up to a front face of the cover film 11. Here, h1 to h3 satisfy an expression (I) below.

h1<h2<h3 (1)

As illustrated in FIG. 4, the expression (I) shows that the tip of the projection 15 is positioned above the upper face of the functional layer 13 and below the upper face of the cover film 11. Note that the functional layer 13, applied for each of the sub-pixels 100, could be left on the projection 15. Here, h2 is a height of the projection 15 itself, and does not include the thickness of the functional layer 13 formed on the projection 15.

Preferably, the light-emitting element layer 10 according to this embodiment further includes the upper electrode 14. Here, h4 is a shortest distance from an upper face of the pixel electrode 12 to a lower face, of the upper electrode 14, not overlapping the projection. The projection 15 and the upper electrode 14 preferably satisfy an expression (II) below.

h4<h2 (II)

Note that the upper electrode 14 stacked above the functional layer 13 overlaps the tip of the projection 15. Here, h4 is a shortest distance up to the lower face, of the upper electrode 14, not overlapping the projection 15. That is, the expression (II) shows that the lower face of the upper electrode 14 is below the upper end of the projection 15.

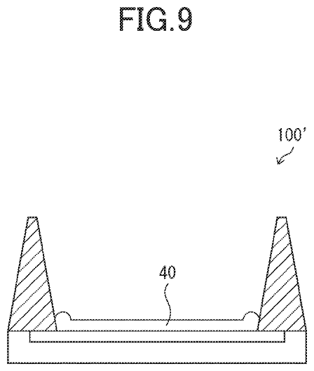

Advantageous effects of such features are specifically described below, with reference to FIGS. 4 and 9. FIG. 9 is a cross-sectional view schematically illustrating a film formed on a sub-pixel 100′ of a display device according to a comparative example. Note that the sub-pixels in FIGS. 4 and 9 are of the same size.

In the sub-pixel 100′ of the display device according to the comparative example, the projection 15 is not formed. As illustrated in FIG. 9, in the sub-pixel 100′ of the display device according to the comparative example, opposing ends of a film 40 alone; that is, ends of the sub-pixel region alone, are extremely thick. This variation in film thickness is caused by what is referred to as the coffee ring effect.

Meanwhile, in the sub-pixel 100 illustrated in FIG. 4 according to this embodiment, the coffee ring effect occurs on opposing ends of the light-emitting region; whereas, the coffee ring effect also occurs in a region adjacent to the projection 15. Such a feature increases thick portions, so that the variation in film thickness inside the light-emitting region is smaller in this embodiment than in the comparative example. Hence, the inside of the sub-pixel 100 according to this embodiment is highly uniform in film thickness, and the light-emitting area becomes wider.

Note that, if the functional layer 13 is stacked to overlap the pixel electrode 12 and the projection 15, the functional layer 13 is formed above the projection 15. Since the functional layer 13 here is extremely thin, the shape of the projection 15 transfers to the functional layer 13 above the projection 15. Hence, even if an other functional layer is further formed and stacked, asperities of the functional layer below serve as projections by appearance, contributing to high uniformity in film thickness inside the sub-pixel. Consequently, the film thickness of the functional layer 13 formed above can also be highly uniform.

Moreover, the highly uniform film thickness contributes to emission of uniform light inside the sub-pixel, making it possible to optimize a characteristic of a light-emitting cell. Furthermore, the uniform film thickness reduces the risk that the functional layer 13 becomes extremely thin in and around a center of the sub-pixel 100, and thus fails to emit light. Such a feature improves a manufacturing yield of light-emitting cells.

In addition, preferably, the projection 15 and the functional layer 13 further satisfy an expression (III) below.

50 nm≤h2−h1≤200 nm (III)

Note that h1 and h2 are determined as noted above. The expression (III) shows that a difference in height between the tip of the projection 15 and the upper face of the functional layer 13 is 50 nm or greater and 200 nm or smaller.

The difference in height between the tip of the projection 15 and the upper face of the functional layer 13 is preferably 500 nm or greater, more preferably 100 nm or greater, and still more preferably 120 nm or greater. Moreover, the difference in height between the tip of the projection 15 and the upper face of the functional layer 13 is preferably 200 nm or smaller, more preferably 180 nm or smaller, and still more preferably 150 nm or smaller.

A specific height of the projection 15 may be appropriately determined in accordance with the number and the thickness of the functional layers 13. Preferably, the projection 15 has a height of 300 nm or greater. Note that if the sub-pixel 100 includes a plurality of projections 15, a height of each projection 15 can be appropriately determined.

(Shape in Plan View)

Described next is a shape of the projection 15 in plan view, with reference to FIG. 5. FIG. 5 is a top view schematically illustrating a disposition of a projection inside a sub-pixel according to the first embodiment of the present invention.

As illustrated in, for example, FIG. 5, the projection 15 according to this embodiment is preferably shaped into a lattice in plan view.

Here, the coffee ring effect occurs on an edge of the light-emitting region and a region adjacent to the projection 15. In particular, the coffee ring effect occurs in a region inside the lattice. Such a feature increases thick portions, and the variation in film thickness inside the light-emitting region is small. Hence, the sub-pixel 100 according to this embodiment has a wider light-emitting area.

Note that spaces of the lattice shall not be limited to be quadrangular. Alternatively, the spaces may be polygonal or circular.

Furthermore, each space between the projections adjacent to each other is preferably greater than a width of the projections. That is, in this embodiment, a spacing of the lattice is greater than a thickness of the lattice.

In the sub-pixel 100 according to this embodiment, a frame of the lattice; that is, a region overlapping the pixel electrode 12, does not emit light vertically in relation to the display device 500. Hence, the space of the lattice is greater than the width of the lattice, making it possible to narrow the region affecting the display.

The space of the lattice may be appropriately determined in accordance with a material of the projection 15 and the width of the lattice. For example, the space is preferably 10 μm or greater and 50 μm or smaller, more preferably, 15 μm or greater and 40 μm or smaller, and still more preferably 15 μm or greater and 30 μm or smaller.

Note that the spaces of the lattice do not have to be constant.

(Material)

The projection 15 according to this embodiment is preferably formed of an inorganic insulating film. Examples of the inorganic insulating film includes, but not limited to, a photosensitive resin such as an acrylic resin, a polyimide resin, or a fluorine resin, an oxide film, and a nitride film.

When the projection 15 is an inorganic insulating film, a region overlapping the projection 15 does not emit light vertically in relation to the display device 500; however, the projection 15 shaped into a lattice scatters light from a light-emitting portion so that a portion covered with the projection 15 can emit the light obliquely in relation to the display device 500. Such a feature can improve a characteristic of a viewing angle when the light is emitted.

Note that the material of the projection can be appropriately determined in accordance with the shape of the projection.

Described below are sub-pixels in modifications according to this embodiment and sub-pixels according to other embodiments. Note that, as a matter of convenience, identical reference signs are used to denote functionally identical components between the modifications and the embodiments. Such components will not be repeatedly elaborated upon.

First Modification

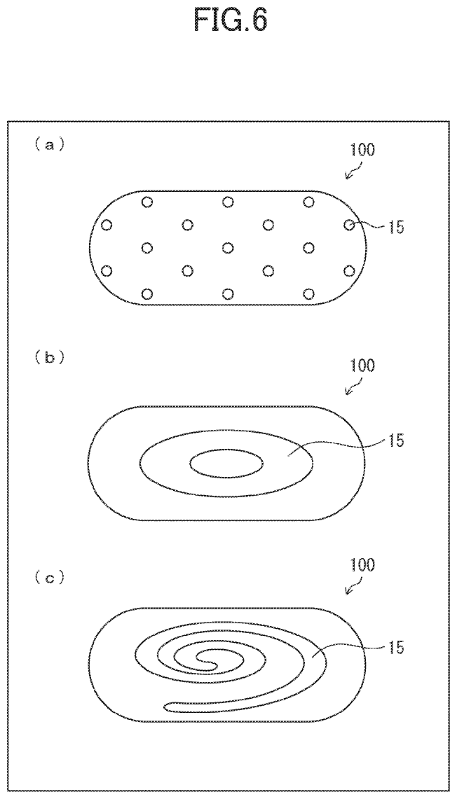

In the above embodiment, the projection 15 is shaped into a lattice in plan view. Alternatively, the projection 15 may be shaped into any give shape. For example, the projection may be shaped into dots in plan view. Such an example is described with reference to an illustration (a) of FIG. 6. FIG. 6 (a) is a top view schematically illustrating a projection according to a first modification of the present invention. The illustration (a) of FIG. 6 shows the projection 15 including a plurality of projections 15 shaped into dots.

A shape of the dots includes such shapes as, for example, polygonal and oval shapes, other than a circular shape. Moreover, a schematic shape of the projection is not necessarily columnar, but is pyramidal, trapezoidal, and polyhedral. The surface of the projection may have various kinds of curves, other than a flat surface. Note that the shape of the projection 15 can be selected appropriately in accordance with a material of the projection 15 and a shape of the sub-pixel.

The sub-pixel 100 may include one projection. Alternatively, in view of enhancing uniformity in film thickness, the sub-pixel 100 preferably includes a plurality of projections as shown in the illustration (a) of FIG. 6. When the plurality of projections are provided, the coffee ring effect occurs even between the projections and increases thick portions, thereby further widening the light-emitting area. Note that the projections are arranged in any given manner.

Each projection has a size (a diagonal length of the base) of preferably 10 μm or smaller, more preferably, 8 μm or smaller, and still more preferably 5 μm or smaller.

Each space between the projections may be appropriately determined in accordance with a material and a width of the projections 15. For example, the space is preferably 10 μm or greater and 50 μm or smaller, more preferably, 15 μm or greater and 40 μm or smaller, and still more preferably 15 μm or greater and 30 μm or smaller.

Note that the spaces between the projections do not have to be constant.

If the projections are shaped into dots, the film is thick around the dots, providing the same advantageous effects as those in the above embodiment.

Second Modification

The projection 15 may be annular in plan view. Such a projection 15 is described with reference to an illustration (b) of FIG. 6. FIG. 6 (b) is a top view schematically illustrating a projection according to a second modification of the present invention. The illustration (b) of FIG. 6 shows the projection 15 shaped annularly.

The annularly shaped projection 15 means that the projection 15 is a hollow circle. Other than the hollow circle, the shape of the projection 15 may be selected from among, for example, a polygon and an ellipse as long as the projection 15 has an opening and an outer periphery and an inner periphery of the projection 15 are independent from each other. Furthermore, a schematic shape of the projection is not necessarily columnar, but is trapezoidal as long as the projection is shaped to have a through opening inside the projection.

If the projection is annular, the coffee ring effect occurs along the outer and inner peripheries of the annular projection, achieving the same advantageous effects as those of the above embodiment. Note that the projection shaped annularly is more preferable than the projections shaped into dots of the same outer diameter because the former allows the coffee ring effect to provide a thick area more widely.

One such projection may be provided. Alternatively, a plurality of such projections may be provided.

Third Modification

The projection 15 may be helical in plan view. Such a projection 15 is described with reference to an illustration (c) of FIG. 6. FIG. 6 (c) is a top view schematically illustrating a projection according to a third modification of the present invention. The illustration (c) of FIG. 6 shows the projection 15 shaped helically.

The helically shaped projection 15 means that the projection 15 is spiral. The direction and the number of turns of the projection 15 are not limited to particular ones as long as the projection 15 is helical. Moreover, a wall of the projection shaped spirally does not have to curve smoothly. Alternatively, the wall may have a point.

If the projection is helical, the coffee ring effect occurs along the outer and inner peripheries of the helix, achieving the same advantageous effects as those of the above embodiment. Note that the projection shaped helically is more preferable than that shaped annularly if both having the same outer diameter because the former allows the coffee ring effect to provide a thick area more widely.

One such projection may be provided. Alternatively, a plurality of such projections may be provided.

### Second Embodiment

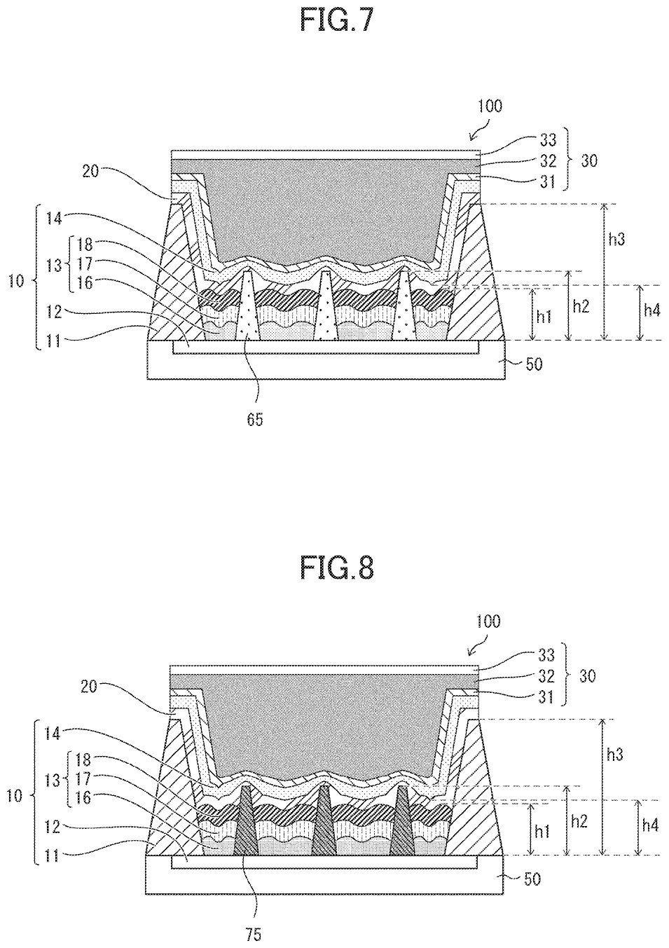

Described below is an other embodiment of the present invention, with reference to FIG. 7. FIG. 7 is a cross-sectional view schematically illustrating the sub-pixel of the display device according to a second embodiment of the present invention.

Note that, as a matter of convenience, identical reference signs are used to denote functionally identical components between this embodiment and the above embodiment. Such components will not be repeatedly elaborated upon.

A projection 65 according to this embodiment is preferably formed of metal. In view of simplifying the method for manufacturing the display device, for example, the projection 65 is preferably made of the same metal as that to be used for the TFT layer 50 (e.g. the metal of wiring).

The projection 65 made of metal is capable of electrically connecting to the pixel electrode 12, functioning as an electrode, and injecting holes into the functional layer 13 as the pixel electrode 12 injects holes, contributing to emission of light from the sub-pixel 100. Such a feature allows the sub-pixel 100 to have a wider light-emitting area.

### Third Embodiment

Described below is still an other embodiment of the present invention, with reference to FIG. 8. FIG. 8 is a cross-sectional view schematically illustrating the sub-pixel of the display device according to a third embodiment of the present invention.

Note that, as a matter of convenience, identical reference signs are used to denote functionally identical components between this embodiment and the above embodiments. Such components will not be repeatedly elaborated upon.

A projection 75 according to this embodiment is preferably formed of the same material as the cover film 11 is. Moreover, the projection is preferably formed in the same layer as the cover film 11 is. That is, the projection is preferably made simultaneously with the cover film 11. In such a case, an example of a method for forming the projection 75 includes simultaneously forming the cover film 11 and the projection 75 together by photolithography, using a grayscale mask.

The projection 75 is formed in the same layer as the cover film 11 is, making it possible to easily manufacture the display device.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### SUMMARY

A display device according to a first aspect of the present invention includes a sub-pixel including a light-emitting element layer. The sub-pixel includes: a first electrode; an edge cover overlapping an end of a front face of the first electrode; a projection projecting from the front face of the first electrode; and a functional layer shaped into an island for each of sub-pixels including the sub-pixel, and formed on the front face of the first electrode. With respect to the front face of the first electrode where a first height is a height up to a front face of a protrusion of the functional layer provided along an edge of the projection, a second height is a height up to a tip of the projection, and a third height is a height up to a front face of the edge cover, the second height is greater than the first height and smaller than the third height.

Thanks to this feature, the inside of the sub-pixel is highly uniform in film thickness, further widening the light-emitting area. Moreover, the highly uniform film thickness contributes to emission of uniform light inside the sub-pixel, making it possible to optimize a characteristic of a light-emitting cell. Furthermore, the uniform film thickness reduces the risk that the functional layer becomes extremely thin in and around a center of the sub-pixel, and thus fails to emit light. Such a feature improves a manufacturing yield of light-emitting cells.

In the display device according to a second aspect of the present invention, the sub-pixel further includes a second electrode above the functional layer, and where a fourth height is a shortest distance from the front face of the first electrode to a lower face, of the second electrode, not overlapping the projection, the fourth height is smaller than the second height.

Thanks to this feature, even if the functional layer is formed above the projection, the shape of the projection transfers to the functional layer above the projection. Hence, even if an other functional layer is further formed and stacked, asperities of the functional layer below serve as projections by appearance, contributing to high uniformity in film thickness inside the sub-pixel. The feature can also make highly uniform the film thickness of the functional layer formed above. Even if an other functional layer is further formed and stacked, the reduction in the light-emitting area can be curbed.

In the display device according to a third aspect of the present invention, the sub-pixel further includes a sealing layer above the edge cover. Thanks to this feature, an active element formed in the TFT layer is individually driven, so that the sub-pixel corresponding to the driven active element can be individually controlled.

In the display device according to a fourth aspect of the present invention, the sub-pixel further includes a sealing layer above the edge cover. This feature makes it possible to keep such an impurity as water or oxygen outside from reaching inside the light-emitting element layer.

In the display device according to a fifth aspect of the present invention, the projection is shaped into a lattice in plan view. Thanks to this feature, the coffee ring effect occurs on an edge of a light-emitting region and in a region adjacent to the projection. In particular, the coffee ring effect in a region inside the lattice. Such a feature increases portions having a great film thickness, so that the variation in film thickness inside the light-emitting region is small. Hence, the sub-pixel according to this embodiment has a wider light-emitting area.

In the display device according to a sixth aspect of the present invention, a space between projections including the projection and adjacent to each other is greater than a width of the projections. This feature makes it possible to narrow a region overlapping the pixel electrode, thereby narrowing a region affecting the display.

In the display device according to a seventh aspect of the present invention, the projection is shaped into dots in plan view. Thanks to this feature, the film is thick around the dots, making it possible to further widen the light-emitting area.

In the display device according to an eighth aspect of the present invention, the projection is annular or helical in plan view. Thanks to this feature, the film is thick around an outer periphery and an inner periphery of the annular projection, making it possible to further widen the light-emitting area.

In the display device according to a ninth aspect of the present invention, the projection includes a plurality of projections. Such a feature allows the coffee ring effect to occur between the projections, making it possible to provide an area having a great film thickness more widely. Consequently, the inside of the sub-pixel can be highly uniform in film thickness, and the light-emitting area within the sub-pixel can be wider.

In the display device according to a tenth aspect of the present invention, the tip of the projection is positioned above the upper face of the functional layer, and a difference in height between the tip and the upper face is 50 nm or greater and 200 nm or smaller. Thanks to this feature, the coffee ring effect caused by the projection can occur on a layer formed above the functional layer. Moreover, the feature can reduce an effect to an upper electrode, such as disconnection due to the projection.

In the display device according to an eleventh aspect of the present invention, the projection is formed of an inorganic insulating film. Thanks to this feature, the projection serves as a region not to emit light, and a portion of a film covered with the projection shaped into a lattice can emit the light obliquely in relation to the display device. Hence, the feature can improve a characteristic of a viewing angle when the light is emitted.

In the display device according to a twelfth aspect of the present invention, the projection is formed of metal. Thanks to this feature, the projection, functioning as an electrode, can electrically connect to the first electrode (a pixel electrode) and inject holes into the functional layer as the first electrode (the pixel electrode) injects holes, contributing to emission of light from the sub-pixel. Hence, the sub-pixel 100 can have a wider light-emitting area.

In the display device according to a thirteenth aspect of the present invention, the projection is formed in the same layer, and of the same material, as the edge cover is. Such a feature makes it possible to easily manufacture the display device.

In the display device according to a fourteenth aspect of the present invention, the functional layer includes a light-emitting layer, a hole-injection layer, and a hole-transport layer, and each of the light-emitting layer, the hole-injection layer, and the hole-transport layer contains a liquid material. In the display device according to a fifteenth aspect of the present invention, the liquid material in a solution has a concentration of 10 w % or lower.

Thanks to this feature, droplets delivered or applied by ink-jet printing or coating dry quickly, making it possible to form the layers fast.

### INDUSTRIAL APPLICABILITY

The present invention is applicable to manufacture of, for example, a light-emitting cell of an organic EL display device.

### REFERENCE SIGNS LIST

10 Light-Emitting Element Layer
11 Cover Film (Edge Cover)
12 Pixel Electrode (First Electrode)
13 Functional Layer
14 Upper Electrode (Second Electrode)
15 [symbol] 65 [symbol] 75 Projection
16 Hole-Injection Layer
17 Hole-Transport Layer
18 Light-Emitting Layer
20 Common Layer
30 Sealing Layer
40 Film
50 TFT Layer
100 [symbol] 100′ Sub-Pixel
103 Barrier Layer
110 Lower-Face Film
111 Bonding Layer
112 Resin Layer
115 Semiconductor Film
116 First Inorganic Insulating Film
118 Second Inorganic Insulating Film
120 Third Inorganic Insulating Film
121 Planarization Film
139 Functional Film
500 Display Device
CE Capacitance Electrode
GE Gate Electrode
SH Source Wire
Tr Thin-Film Transistor (TFT)

1. A display device, comprising
a sub-pixel including a light-emitting element layer,
the sub-pixel including:
a first electrode;
an edge cover overlapping an end of a front face of the first electrode;
a projection projecting from the front face of the first electrode; and
a functional layer shaped into an island for each of sub-pixels including the sub-pixel, and formed on the front face of the first electrode, wherein
with respect to the front face of the first electrode where a first height is a height up to a front face of a protrusion of the functional layer provided along an edge of the projection, a second height is a height up to a tip of the projection, and a third height is a height up to a front face of the edge cover, the second height being greater than the first height and smaller than the third height,
the projection is annular or helical in plan view.

2. The display device according to claim 1, wherein
the sub-pixel further includes a second electrode above the functional layer, and
where a fourth height is a shortest distance from the front face of the first electrode to a lower face, of the second electrode, not overlapping the projection,
the fourth height is smaller than the second height.

3. The display device according to claim 1, wherein
the sub-pixel further includes a TFT layer below the light-emitting element layer.

4. The display device according to claim 1, wherein
the sub-pixel further includes a sealing layer above the edge cover.

5. (canceled)

6. (canceled)

7. (canceled)

8. (canceled)

9. The display device according to claim 1, wherein
the projection includes a plurality of projections.

10. The display device according to claim 1, wherein
the tip of the projection is positioned above the upper face of the functional layer, and a difference in height between the tip and the upper face is 50 nm or greater and 200 nm or smaller.

11. The display device according to claim 1, wherein
the projection is formed of an inorganic insulating film.

12. The display device according to claim 1, wherein
the projection is formed of metal.

13. The display device according to claim 1, wherein
the projection is formed in the same layer, and of the same material, as the edge cover is.

14. The display device according to claim 1, wherein
the functional layer includes a light-emitting layer, a hole-injection layer, and a hole-transport layer, and
each of the light-emitting layer, the hole-injection layer, and the hole-transport layer contains a liquid material.

15. The display device according to claim 14, wherein
the liquid material in a solution has a concentration of 10 w % or lower.
